(19) United States
(12) Patent Application Publication
(10) Pub. No.: US 2025/0277682 A1
(43) Pub. Date: Sep. 4, 2025

(54) DEVICES WITH ENVIRONMENTAL STRESS INDICATORS

(71) Applicant: Micron Technology, Inc., Boise, ID (US)

(72) Inventors: Charles E. Siko, Boise, ID (US); Joao Elmiro da Rocha Chaves, Middleton, ID (US); Kaleb A. Wilson, Caldwell, ID (US)

(21) Appl. No.: 19/056,756

(22) Filed: Feb. 19, 2025

Related U.S. Application Data
(60) Provisional application No. 63/561,056, filed on Mar. 4, 2024.

(51) Int. Cl. G01D 5/251

(52) U.S. Cl. CPC G01D 5/251

(57) ABSTRACT

Systems, apparatuses, and methods related to a substrate with one or more environmental stress indicators configured to detect and log environmental stress are described. The environmental stress indicators are configured to change a continuity state when exposed to one or more environmental stresses, such as heat and/or mechanical stress. Thus, the environmental stress indicators provide an indication of the environmental stress experienced by the substrate.

### CROSS-REFERENCE TO RELATED APPLICATION(S)

The present application claims priority to U.S. Provisional Patent Application No. 63/561,056, filed Mar. 4, 2024, the disclosure of which is incorporated herein by reference in its entirety.

### TECHNICAL FIELD

This disclosure relates generally to devices, and more particularly, to electronic devices having circuit substrates with indicators for notifying environmental stress.

### BACKGROUND

Electronic components are mounted on a substrate, such as a printed circuit board (PCB), for an electronic device. During manufacturing and operation, the components and the PCB may receive environmental stress, such as resulting from extreme temperatures and/or excessive mechanical force, that may damage the electronic device. For example, the manufacturing process for the device may require relatively higher temperatures. Also, the device may be subject to excessively high temperatures and/or mechanical stresses, such as bending forces on the PCB, during operation of the device. The overlapping causes may cause difficulties in pinpointing the source of the damaging stress. In other words, it can be difficult to determine when and/or how the damage occurred, further increasing the difficulties in diagnosing and preventing damages to subsequent devices.

### BRIEF DESCRIPTION OF THE DRAWINGS

FIG. 1A illustrates a perspective view of an electronic device, in accordance with one or more embodiments of the present technology.

FIG. 1B illustrates a partial cross-sectional view of the electronic device along a line 1B-1B of FIG. 1A in accordance with one or more embodiments of the present technology.

FIG. 2 illustrates a perspective view of the electronic device under mechanical stress in accordance with one or more embodiments of the present technology.

FIG. 3 illustrates a cross-sectional view of a first example mounted indicator in accordance with one or more embodiments of the present technology.

FIG. 4 illustrates a cross-sectional view of a second example mounted indicator in accordance with one or more embodiments of the present technology.

FIG. 5A and FIG. 5B illustrate cross-sectional views of a third example mounted indicator in accordance with one or more embodiments of the present technology.

FIG. 6 is a flow diagram illustrating an example method of manufacturing an electronic device in accordance with one or more embodiments of the present technology.

FIG. 7 is a schematic view of a system that includes an apparatus in accordance with embodiments of the present technology.

### DETAILED DESCRIPTION

An electronic device can include a substrate, such as a printed circuit board (PCB), that provides a structural support and electrical connections for electronic components (e.g., analog components, digital components, integrated circuits, or the like) mounted thereon. The PCB can include one or more environmental stress indicators configured to detect and log environmental stress, such as excessive heat (e.g., over a predetermined threshold) and/or mechanical stress, experienced by the electronic device. In some embodiments the PCB with one or more environmental stress indicators can be incorporated into a Solid State Drive (SSD) system.

Some examples of the environmental stress indicators can include manufacturing stress indicators, structural stress indicators and/or operating stress indicators. The manufacturing stress indicators can be configured to identify and log excessive stresses (e.g., temperatures exceeding a predetermined threshold) experienced by the electronic device during the manufacturing process. The structural stress indicators can be configured to identify and log excessive stresses (e.g., excessive bending force) applied on the PCB, such as when or while the electronic device is connected/inserted in a corresponding slot during operation. The operating stress indicators can be configured to identify and log excessive thermal conditions experienced by the PCB during operation.

In some embodiments, the environmental stress indicators can include breakable continuity loops, such as brittle conductors and/or thinner traces (e.g., having less than a threshold width), configured to physically break and disconnect electrical connection in response to environmental stress. The breakable continuity loops can be located directly on or directly underneath a top layer (e.g., a passivation layer or a solder mask) and/or a bottom layer. Additionally or alternatively, the environmental stress indicators can include mounted indicators that are configured to switch connectivity states, such as by physically open or close electrical connections, in response to environmental stress.

The environmental stress indicators can provide increased improvability for the electronic devices by logging the type and/or timing (e.g., during manufacturing or post-production) of the damaging stress. Accordingly, the manufacturing process and/or the operating environment can be addressed to decrease subsequent failures.

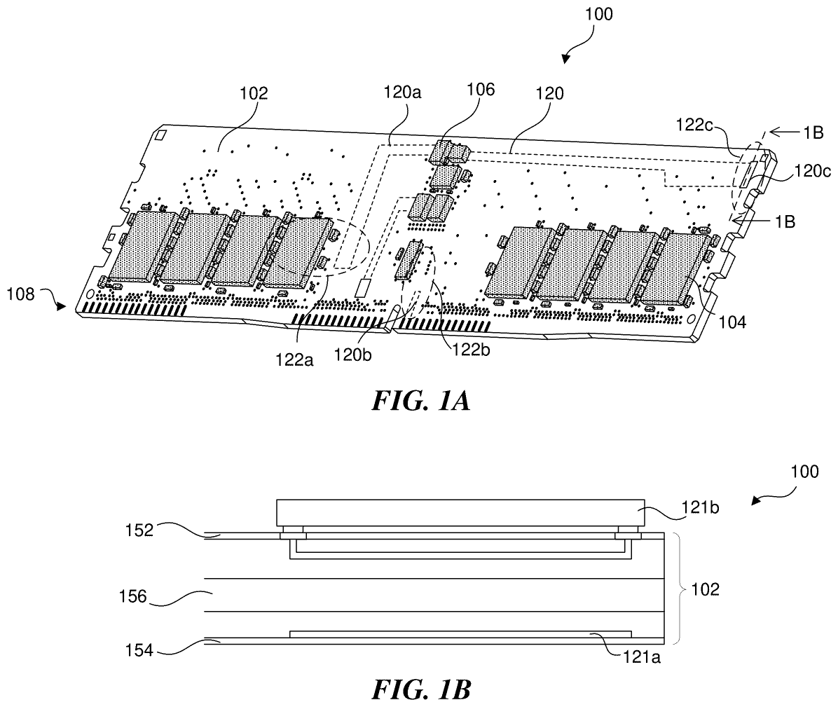

FIG. 1A illustrates a perspective view of an electronic device 100, in accordance with one or more embodiments of the present technology. The electronic device 100 can include a functional module, such as a memory module (e.g., in-line memory module). The electronic device 100 can include components 104 mounted on a substrate 102 (e.g., PCB). The mounted components 104 can include semiconductor devices, such as integrated circuit (IC) devices, memory chips, and the like. The mounted components 104 can further include a controller 106 configured to control operation of one or more circuits on the functional module. For example, the controller 106 can include a memory controller and other components 104 can include memory chips (e.g., dynamic random-access memories (DRAMs)). In some embodiments, the controller 106 and other components 104 can form part of an SSD system (e.g., wherein the controller 106 is a memory controller and the other components 104 include memory chips, such as NAND flash memory) that can be incorporated into personal computers, other personal electronic devices, data center applications, Internet of Things (IoT) applications, automotive technologies, and the like.

The electronic device 100 can include a connector 108 configured to provide an externally communicative interface. For example, the connector 108 can be configured to allow the memory module to be inserted into a slot on a system substrate (e.g., a mother board) and electrically coupled to other circuits (e.g., a host/processor) thereon. The electrical device 100 can include electrical connections within the substrate 102 that electrically couple the connector 108 and/or the mounted components.

The electrical device 100 can have failures, such as physical breaks in the internal connections and/or the mounted connections, damages to the mounted components, and the like. Such structural failures can be caused by environmental stress. For example, environmental temperatures exceeding manufacturing or operating thresholds can cause structural damages. Also, physical stresses, such as excessive bending forces on the PCB, can cause structural damages.

To determine, log, and address the sources of such failures, the electrical device 100 can include one or more environmental stress indicators 120. The environmental stress indicators 120 can include structures/components configured to permanently change physical states in response to one or more targeted environmental stresses. For example, the environmental stress indicators 120 can effectively include a fuse that permanently changes an electrical continuity state, such as from a conductive path to an open circuit or from an open circuit to a conductive path, in response to detecting the one or more targeted environmental stresses.

The environmental stress indicators 120 can include or be coupled to a signal or a continuity loop that is coupled to a measuring circuit. For example, the environmental stress indicators 120 can provide a continuity loop that is initially closed or opened and accessible to the controller 106, one of the other components 104 (e.g., power management IC (PMIC)), and/or an external circuit (e.g., host) through the connector 108. The connected circuit can be configured to confirm the initial state at a predetermined time, such as during device power up. When the environmental stress indicators 120 are in a different continuity state than the initial configuration, the connected circuit can detect that an excessive stress has been applied to the circuit and provide a corresponding record or notification.

Some examples of the environmental stress indicators 120 can include manufacturing stress indicators 120a, structural stress indicators 120b, and/or operating stress indicators 120c. The manufacturing stress indicators 120a can include structures/circuits configured to physically respond to one or more excessive stresses that may occur during the manufacturing process. For example, the manufacturing stress indicators 120a can include temperature sensitive structures configured to change a persistent continuity state in response to detecting an environmental temperature that exceeds a predetermined threshold temperature. The structural stress indicators 120b can include structures/circuits configured to physically respond to one or more excessive mechanical forces that may occur post-production. For example, the structural stress indicators 120b can include force-sensitive structures configured to change a persistent continuity state in response to a shock or a structural deformation that exceeds a predetermined amount. The operating stress indicators 120c can include structures/circuits configured to physically respond to one or more excessive environmental temperatures that may occur post-production. For example, the operating stress indicators 120c can include temperature sensitive structures configured to change a persistent continuity state in response to detecting an environmental temperature that exceeds a predetermined threshold temperature. The operating stress indicators 120c can have a different threshold, a different structure, a different mounting location, and/or the like in comparison to the manufacturing stress indicators 120a.

The electronic device 100 can have the different types of the environmental stress indicators 120 at targeted locations, such as locations that are more susceptible to the targeted stress. For example, the manufacturing stress indicators 120a can be located in or within a threshold distance from manufacturing stress zones 122a on the PCB 102. The manufacturing stress zones 122a can include locations on the PCB 102 targeted to be subject to higher temperatures, such as portions adjacent to mounting locations. Also, the structural stress indicator 120b can be located in or within a threshold distance from structural stress zones 122b on the PCB 102. The structural stress zones 122b can include locations on the PCB 102 (e.g., within a threshold distance from the connector 108 or about a midpoint along a length or a width) likely to be subject to post-production mechanical stress. Further, the operating stress indicators 120c can be located in operating stress zones 122c on the PCB 102. The operating stress zones 122c can include locations on the PCB 102 that are less likely to be affected by the manufacturing environment and more likely to be affected by post-production ambient environment.

A manufacturer, a designer, a developer, or the like can assess the corresponding environments and the electronic device 100 to determine the targeted locations. For example, a computing system can use the manufacturing parameters (e.g., temperatures), PCB dimensions, component locations, component material, operating environments, and/or the like as input parameters to computer models and simulate/estimate stress patterns. Based on the simulation, the computing system can derive the locations more susceptible to stress or most likely to be able to detect and log the stress applied to the electronic device 100.

To describe the different attachment and integration details of the environmental stress indicators 120, FIG. 1B illustrates a partial cross-sectional view of the electronic device 100 along a line 1B-1B of FIG. 1A in accordance with one or more embodiments of the present technology. In some embodiments, the electronic device 100 can include the environmental stress indicators 120 which can be mounted over the substrate 102, integrated into or embedded in the substrate 102, or a combination thereof.

As an illustrative example, the electronic device 100 can include an integrated indicator 121a (e.g., an integrated instance of the environmental stress indicator 120) integrated into or embedded in the substrate 102. In some embodiments, the integrated indicator 121a can be on or disposed between an outer-most layer (e.g., a protection layer, such as a passivation layer or a solder mask) and a directly-underneath layer. For example, the integrated indicator 121a can be immediately underneath a top protection layer 152 or a bottom protection layer 154 and away from a substrate core 156 (e.g., a PCB core, such as FR-4 or a dielectric center portion). The peripheral or near-surface placement of the integrated indicator 121a can allow the indicator to be exposed to and accurately assess the applied stress.

In addition to the depth/location, the integrated indicator 121a can include an electrical conductor having a weaker physical characteristic in comparison to other electrical conductors (e.g., traces) on the substrate 102. For example, the integrated indicator 121a can have an oval cross-sectional shape, a thinner width (e.g., 0.2 mm or less), a different or more brittle material/alloy, or a combination thereof in comparison to traces. Accordingly, the integrated indicator 121a can be configured to physically break in response to a mechanical stress, such as when the PCB is bent or flexed beyond a maximum amount.

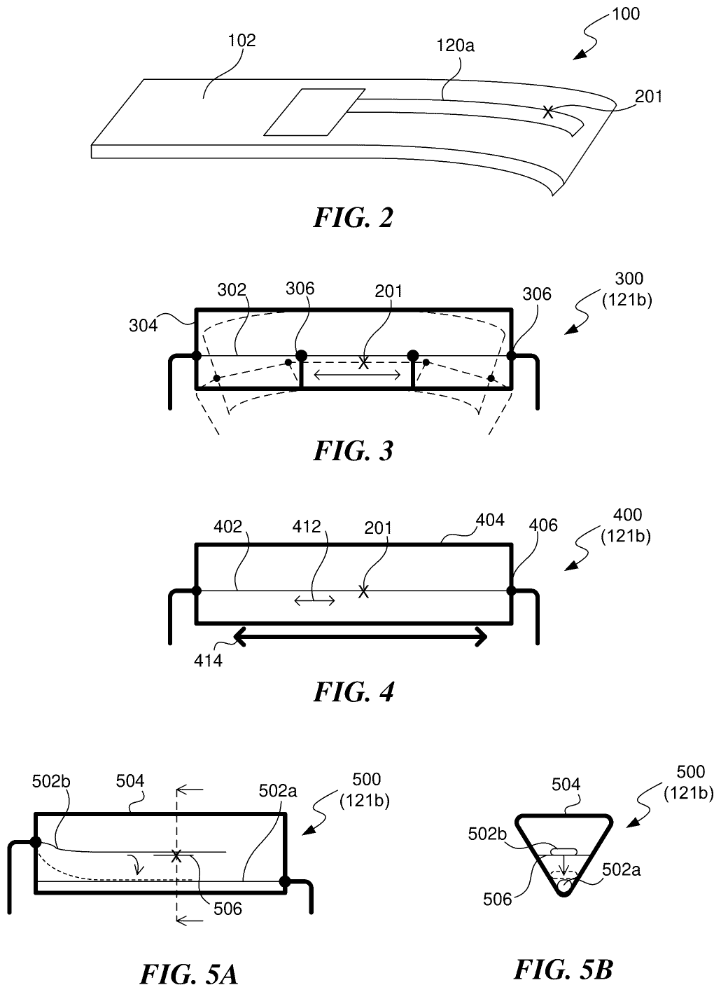

In describing the breaking condition of the integrated indicator 121a, FIG. 2 illustrates a perspective view of the electronic device 100 under mechanical stress in accordance with one or more embodiments of the present technology. In referring to FIG. 1B and FIG. 2 together, the bend/flex in the substrate 102 can flex and/or stretch the integrated indicator 121a beyond its structural limit. As a result, the integrated indicator 121a can fail or physically break, thereby creating a continuity disruption 201 in the continuity loop coupled to the measuring device (e.g., a chip mounted on the PCB).

Additionally or alternatively, the integrated indicator 121a can have a different coefficient of thermal expansion (CTE) than the surrounding structures. The different CTE can allow the integrated indicator 121a to expand less than the surrounding structures under higher temperature. The shape/location of the integrated indicator 121a and/or the CTE mismatch can be controlled such that the integrated indicator 121a is stretched beyond a breaking point above a predetermined threshold temperature. Accordingly, the integrated indicator 121a can form the continuity disruption 201 when the environmental temperature is above the threshold temperature and/or sustained for a minimum duration. The integrated indicator 121a can be configured such that the continuity disruption 201 is maintained even after returning to lower temperatures.

Referring back to FIG. 1B, the electronic device 100 can include a mounted indicator 121b (e.g., a surface-mounted instance of the environmental stress indicator 120) attached on/over the substrate 102. Similar to other components, the mounted indicator 121b can be surface mounted to a top/bottom surface of the substrate 102. The mounted indicator 121b can also be electrically coupled to a continuity loop that is further coupled to a measuring device. The continuity loop can be deeper or closer to the core 156 than the integrated indicator 121a. In some embodiments the continuity loop is directly adjacent to an exterior surface of the substrate 102. In other embodiments, the integrated indicator 121a can be electrically coupled to the mounted indicator 121b.

Like the integrated indicator 121a, the mounted indicator 121b can be physically configured to detect and log the targeted conditions, such as by switching a persistent state in response to one or more targeted environmental conditions. Some examples of physical configurations for the mounted indicator 121b can be described in FIG. 3-FIG. 5B.

FIG. 3 illustrates a cross-sectional view of a first example mounted indicator 300 (e.g., an instance of the mounted indicator 121b of FIG. 1B) in accordance with one or more embodiments of the present technology. The mounted indicator 300 can be configured to determine and log mechanical stress, such as by having a breakable conductor 302 (e.g., brittle or thinner conductor) encased in a housing 304. The breakable conductor 302 can be physically connected to the housing 304 at conductor physical attachments 306. In some embodiments, the housing 304 can be flexible and bend or twist in response to the mechanical stress. The conductor physical attachments 306 can be fixed to the housing 304 and move with the bend and twist thereof. Accordingly, the separation distance and/or the relative arrangement between the conductor physical attachments 306 can change or lengthen, thereby creating the continuity disruption 201 by stretching and physically breaking the breakable conductor 302.

FIG. 4 illustrates a cross-sectional view of a second example mounted indicator 400 (e.g., an instance of the mounted indicator 121b of FIG. 1B) in accordance with one or more embodiments of the present technology. Like the indicator 300 of FIG. 3, the mounted indicator 400 can be configured to determine and log thermal stress, such as by having a breakable conductor 402 (e.g., brittle or thinner conductor) encased in a housing 404 and physically connected to the housing 404 at conductor physical attachments 406 that are fixed to the housing 404.

The housing 404 and the breakable conductor 402 can have different thermal reactivity, such as differing CTEs. For example, the housing 404 can have a first temperature response 412 (e.g., shape and/or CTE) and the breakable conductor 402 can have a second temperature response 414 different than the first temperature response 412. For a given temperature, the different temperature responses can allow the housing 404 to expand more than the breakable conductor 402. Accordingly, the distance between the conductor physical attachments 406 can increase more than the expanded length of the breakable conductor 402, thereby physically breaking the conductor 402 and creating the continuity disruption 201. The housing 404 and breakable conductor 402 can be configured such that the continuity disruption 201 is maintained even after returning to lower temperatures.

FIG. 5A and FIG. 5B illustrate cross-sectional views of a third example mounted indicator 500 in accordance with one or more embodiments of the present technology. Referring to FIG. 5A and FIG. 5B together, the indicators 300 and 400 are configured to have an initially continuous state and permanently switch to an open state in response to a predetermined thresholding condition. In comparison, the mounted indicator 500 can illustrate an example of an indicator configured to have an initially open state and permanently switch to a closed/connected state in response to a predetermined thresholding condition.

As an illustrative example, the mounted indicator 500 can have a first conductor 502a and a second conductor 502b encased in a housing 504. The first conductor 502a and the second conductor 502b can be physically separated and electrically isolated from each other. In some embodiments, the mounted indicator 500 have a breakable separator 506 physically connected to the housing 504 and configured (e.g., location, shape, orientation, etc.) to maintain the separation between the first conductor 502a and the second conductor 502b. The breakable separator 506 can be configured to respond, such as by physically breaking, to the targeted stress. For example, the breakable separator 506 can include a relatively brittle material (e.g., glass or thin plastic material) that is connected to a more flexible housing as described above for responding to mechanical stress. Also, the breakable separator 506 can include a material having a different CTE than the housing 504 for responding to thermal stress. Accordingly, the breakable separator 506 can be configured to structurally fail in response to the stress and allow the first conductor 502a to physically contact the second conductor 502b and form an electrical connection.

In some embodiments, the housing 504 and/or the conductors can have configurations that increase the likelihood of switching connectivity states in response to stress events. For example, the breakable separator 506 can keep the second conductor 502b over the first conductor 502a. The housing 504 can have a cross-sectional shape of an inverted triangle with the first conductor 502a located within the bottom corner. When the breakable separator 506 fails, the inverted triangular shape can guide the second conductor 502b onto the first conductor 502a and enable a direct contact between the two conductors. Additionally or alternatively, the first conductor 502a can have a cross-sectional shape of an oval or a triangle to fit within the corner of the housing 504. In contrast, the second conductor 502b can have a wider or a flatter cross-section shape to increase the likelihood of direct contact with the first conductor 502a.

The environmental stress indicators 120 can provide increased improvability for the electronic device 100 by logging the type and/or timing (e.g., during manufacturing or post-production) of targeted stress, such as temperature or mechanical force exceeding a threshold. The collected data can be used to identify and address the source of such stress in the corresponding environment (e.g., during manufacturing or post-production operation). Further, by logging a stress event, the environmental stress indicators 120 can provide notifications for potential circuit issues. The measuring circuit can use the stress indication to deviate from normal operations, such as the power up sequence, and check for the potential circuit issues. Accordingly, the environmental stress indicators 120 can provide the opportunity to prevent catastrophic failures, such as overheating, complete data loss, or the like, that may result from operating with failed circuits (e.g., unintended shorts).

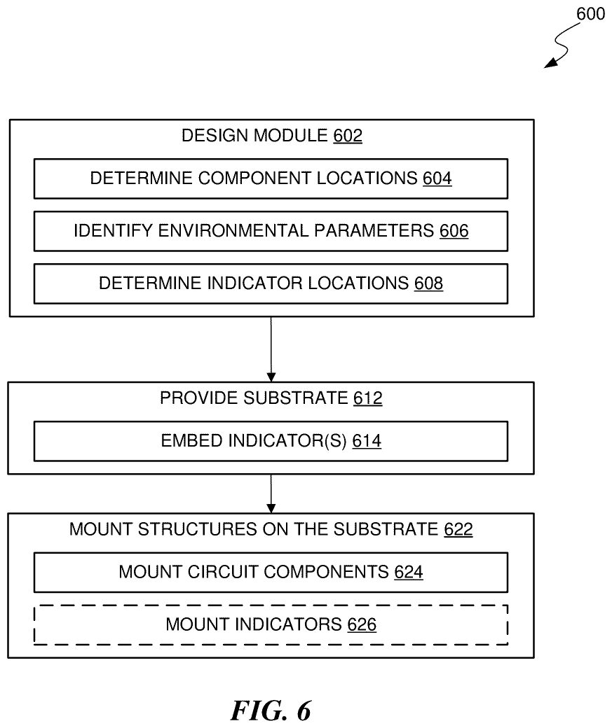

FIG. 6 is a flow diagram illustrating an example method 600 of manufacturing an electronic device (e.g., the electronic device 100 of FIG. 1A, the substrate 102 of FIG. 1, the environmental stress indicators 120 of FIG. 1, and/or the like) in accordance with one or more embodiments of the present technology. In some embodiments, the method 600 can be for manufacturing a module, such as an in-line memory module having environmental stress indicators.

At block 602, the method 600 can include designing the module. In designing the module, a computing system can identify (1) circuits and corresponding components (e.g., the components 104 of FIG. 1A or the like), (2) electrical connections (e.g., traces) between the components, and (3) environmental stress indicators (e.g., the environmental stress indicators 120 of FIG. 1A or the like) on a PCB. The computing system can identify the circuit components, such as a type and a quantity of memory chips, based on the targeted use of the module. The computing system can compute the number/type of stress indicators (e.g., the manufacturing stress indicators, structural stress indicators, and/or operating stress indicators discussed above in FIG. 1A or the like) according to one or more parameters, such as manufacturing and/or operating environment parameters (e.g., temperatures), PCB dimensions, component material, and/or the like. Moreover, the computing system can compute the locations of the components, the connections, and the environmental stress indicators.

As an illustrative example of the module design, at block 604, the method 600 can include determining component locations, such as for the components 104 or the like, on the PCB. The components can be arranged according to one or more operating parameters, such as the physical space requirement and/or the targeted operating parameters. Also, the components can be arranged according to one or more industry standards.

At block 606, the method 600 can include determining environmental parameters for the module. For example, the computing system can use an intended downstream customer or a corresponding operating environment (e.g., enterprise or server application, laptop usage, Artificial Intelligence module application, etc.) to identify manufacturing, structural, and/or operating stress-related parameters. The computing system can determine one or more predetermined environmental parameters (e.g., temperature and/or physical shock or vibration characteristics) or corresponding computer models associated with the identified customer or environment.

At block 608, the method 600 can include determining environmental stress indicator locations (e.g., for the environmental stress indicators 120 or the like). For example, the computing system can use manufacturing parameters (e.g., temperatures), PCB dimensions, component locations, component material, operating environments, and/or the like as input parameters to computer models to simulate/estimate stress patterns. Based on the simulation, the computing system can derive the locations (e.g., one or more of the stress zones described above) more susceptible to stress or most likely to be able to detect and log the stress applied to the module. In some embodiments the environmental stress indicators can be located in or within a threshold distance from stress zones targeted to be subject to higher temperatures (e.g., portions adjacent to component mounting locations). In some embodiments, the indicators can be located in or within a threshold distance from stress zones likely to be subject to post-production mechanical stress (e.g., within a threshold distance from a connector or about a midpoint along a length or a width). In some embodiments, the indicators can be located in or within a threshold distance from stress zones likely be more effected by a post-production temperatures than by the manufacturing environment.

Once the module design is complete, the method 600 can include providing a substrate as illustrated in block 612. For example, the method 600 can include obtaining a PCB having the traces and mounting locations that correspond to the completed design. Moreover, providing the substrate can include preparing the PCB for surface mount. Alternatively, the PCB can be provided by manufacturing the PCB or one or more portions thereof (e.g., surface connections, vias, etc.) according to the completed design.

In some embodiments, providing the substrate can include embedding or integrating one or more environmental stress indicators as illustrated at block 614. In some embodiments, the embedded indicator (e.g., the integrated indicator 121a of FIG. 1B or the like) can be on or disposed between an outer-most layer (e.g., a protection layer, such as a passivation layer or a solder mask) and a directly-underneath layer. For example, the embedded indicator can be immediately underneath a top protection layer or a bottom protection layer and closer to the outer-most layer than a substrate core (e.g., a PCB core, such as FR-4 or a dielectric center portion). The embedded indicator can be co-planar with an outer-most signal routing layer and/or pads. The peripheral or near-surface placement of the embedded indicator can allow the indicator to be exposed to and accurately assess the applied stress. In some embodiments, the embedded indicators can include breakable continuity loops, such as brittle conductors and/or thinner traces (e.g., having less than a threshold width or a width of the signal-carrying traces), configured to physically break and disconnect electrical connection in response to environmental stress. The breakable continuity loops can be located directly on or directly underneath the outer-most layer and the directly-underneath layer. In some embodiments, the continuity loop can be electrically coupled to a measuring device or a set of corresponding connection points.

In some embodiments, the embedded indicator can include an electrical conductor having a weaker physical characteristic in comparison to other electrical conductors (e.g., traces) on the substrate. For example, the embedded indicator can have an oval cross-sectional shape, a thinner width (e.g., 0.2 mm or less), a different or more brittle material/alloy, or a combination thereof in comparison to traces. Accordingly, the embedded indicator can be configured to physically break in response to a mechanical stress, such as when the PCB is bent or flexed beyond a maximum amount. As a result, a continuity disruption occurs in the continuity loop coupled to the measuring device (e.g., a chip mounted on the PCB).

In some embodiments, the embedded indicator can have a different coefficient of thermal expansion (CTE) than the surrounding structures. The different CTE can allow the embedded indicator to expand less than the surrounding structures under higher temperature. The shape/location of the embedded indicator and/or the CTE mismatch can be controlled such that the embedded indicator is stretched beyond a breaking point above a predetermined threshold temperature. Accordingly, the embedded indicator can form the continuity disruption when the environmental temperature is above the threshold temperature and/or sustained for a minimum duration. The embedded indicator can be configured such that the continuity disruption is maintained even after returning to lower temperatures.

At block 622, the method 600 can include mounting structures, such as the components 104, the environmental stress indicators 120, and/or the like, on the provided substrate. Block 622 can correspond to a surface mounting process for mounting one or more chips, passive components, environmental stress indicators, etc. on the PCB. For example, at block 624, the method 600 can include mounting the components 104 or the like on the PCB. Likewise, at block 626, the method 600 can include mounting the indicators 121b of FIG. 1B) or the like on the PCB. The PCB can include one or more pads or connection points configured to receive or connect to the mounted indicators 121b per the module design. The indicators 121b can be mounted on/over the designated connectors/pads on the substrate. The mounted indicators can be surface mounted to a top/bottom surface of the substrate. In some embodiments, the mounted indicators can be electrically coupled to a continuity loop that is further coupled to a measuring device (e.g., a chip mounted on the PCB). The continuity loop can be deeper or closer to the core than the embedded indicators. In other embodiments, the embedded indicators can be electrically coupled to the mounted indicators. Additionally or alternatively, the mounted indicators can be configured to switch connectivity states, such as by physically opening or closing electrical connections, in response to environmental stress.

In some embodiments, the mounted indicator can be configured to determine and log mechanical stress, such as by having a breakable conductor (e.g., brittle or thinner conductor) encased in a housing. The breakable conductor can be physically connected to the housing at conductor physical attachments. In some embodiments, the housing can be flexible and bend or twist in response to the mechanical stress. The conductor physical attachments can be fixed to the housing and move with the bend and twist thereof. Accordingly, the separation distance and/or the relative arrangement between the conductor physical attachments can change or lengthen, thereby creating a continuity disruption by stretching and physically breaking the breakable conductor.

In some embodiments, the housing and the breakable conductor can have different thermal reactivity, such as differing CTEs. For example, the housing can have a first temperature response (e.g., shape and/or CTE) and the breakable conductor can have a second temperature response different than the first temperature response. For a given temperature, the different temperature responses can allow the housing to expand more than the breakable conductor. Accordingly, the distance between the conductor physical attachments can increase more than the expanded length of the breakable conductor, thereby physically breaking the conductor and creating the continuity disruption. The housing and breakable conductor can be configured such that the continuity disruption is maintained even after returning to lower temperatures.

In some embodiments, the mounted indicator can be configured to have an initially open state and permanently switch to a closed/connected state in response to a predetermined thresholding condition. For example, the mounted indicator can have a first conductor and a second conductor encased in a housing. The first conductor and the second conductor can be physically separated and electrically isolated from each other. In some embodiments, the mounted indicator has a breakable separator physically connected to the housing and configured (e.g., location, shape, orientation, etc.) to maintain the separation between the first conductor and the second conductor. The breakable separator can be configured to respond, such as by physically breaking, to the targeted stress. For example, the breakable separator can include a relatively brittle material (e.g., glass or thin plastic material) that is connected to a more flexible housing as described above for responding to mechanical stress. Also, the breakable separator can include a material having a different CTE than the housing for responding to thermal stress. Accordingly, the breakable separator can be configured to structurally fail in response to the stress and allow the first conductor to physically contact the second conductor and form an electrical connection.

In some embodiments, the housing and/or the conductors can have configurations that increase the likelihood of switching connectivity states in response to stress events. For example, the breakable separator can keep the second conductor over the first conductor. The housing can have a cross-sectional shape of an inverted triangle with the first conductor located within the bottom corner. When the breakable separator fails, the inverted triangular shape can guide the second conductor onto the first conductor and enable a direct contact between the two conductors. Additionally or alternatively, the first conductor can have a cross-sectional shape of an oval or a triangle to fit within the corner of the housing. In contrast, the second conductor can have a wider or a flatter cross-section shape to increase the likelihood of direct contact with the first conductor.

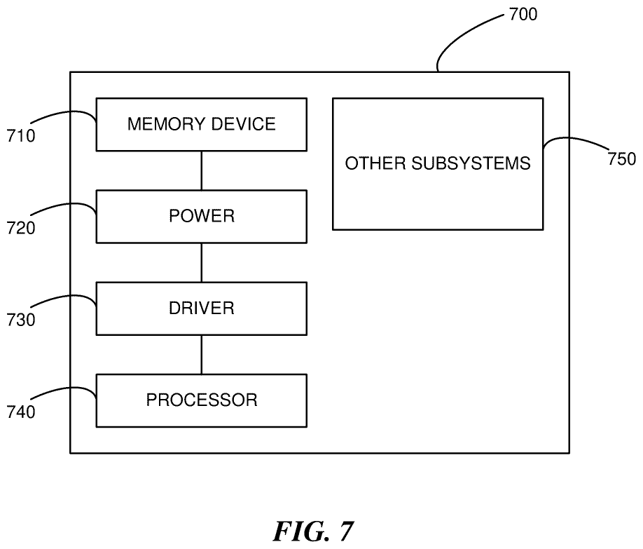

FIG. 7 is a schematic view of a system that includes an apparatus in accordance with embodiments of the present technology. Any one of the foregoing apparatuses (e.g., memory devices) associated with the PCBs described above with reference to FIGS. 1-6 can be incorporated into or implemented in memory (e.g., a memory device 700) or any of a myriad of larger and/or more complex systems, a representative example of which is system 700 shown schematically in FIG. 7. The system 700 can include the memory device 710, a power source 720, a driver 730, a processor 740, and/or other subsystems or components 750.

The memory device 710, as well as the system 700 overall (e.g., the mother board) and/or other portions therein, can include features generally similar to those of the apparatus described above with reference to FIGS. 1-6 and can therefore include various features for performing a direct read request from a host device. The resulting system 700 can perform any of a wide variety of functions, such as memory storage, data processing, and/or other suitable functions. Accordingly, representative systems 700 can include, without limitation, hand-held devices (e.g., mobile phones, tablets, digital readers, and digital audio players), computers, vehicles, appliances and other products. Components of the system 700 may be housed in a single unit or distributed over multiple, interconnected units (e.g., through a communications network). The components of the system 700 can also include remote devices and any of a wide variety of computer readable media.

From the foregoing, it will be appreciated that specific embodiments of the technology have been described herein for purposes of illustration, but that various modifications may be made without deviating from the technology. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the present technology and associated technology can encompass other embodiments not expressly shown or described herein.

In the illustrated embodiments above, the apparatuses have been described in the context of DRAM devices. Apparatuses configured in accordance with other embodiments of the present technology, however, can include other types of suitable storage media in addition to or in lieu of DRAM devices, such as, devices incorporating NAND-based or NOR-based non-volatile storage media (e.g., NAND flash), magnetic storage media, phase-change storage media, ferroelectric storage media, etc.

The term “processing” as used herein includes manipulating signals and data, such as writing or programming, reading, erasing, refreshing, adjusting or changing values, calculating results, executing instructions, assembling, transferring, and/or manipulating data structures. The term data structures includes information arranged as bits, words or code-words, blocks, files, input data, system generated data, such as calculated or generated data, and program data. Further, the term “dynamic” as used herein describes processes, functions, actions or implementation occurring during operation, usage or deployment of a corresponding device, system or embodiment, and after or while running manufacturer's or third-party firmware. The dynamically occurring processes, functions, actions or implementations can occur after or subsequent to design, manufacture, and initial testing, setup or configuration.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to FIGS. 1-7.

I/We claim:

1. An electronic device comprising:
a printed circuit board (PCB); and
an environmental stress indicator mounted on or integrated within the PCB and configured to change a continuity state in response to one or more environmental stresses for permanently logging an occurrence of the one or more environmental stresses.

2. The electronic device of claim 1, wherein the environmental stress indicator integrated into the PCB and disposed between an outer-most layer and a directly-underneath layer of the PCB.

3. The electronic device of claim 2, wherein the environmental stress indicator is configured to change from a conductive state to a disconnected state in response to the one or more environmental stresses.

4. The electronic device of claim 3, further comprising:
signaling traces on or within the PCB, the signaling traces including a metallic material, wherein the environmental stress indicator includes the same metallic material and has a narrower width and/or a shorter thickness than the signaling traces.

5. The electronic device of claim 4, wherein:
the PCB includes an external connector configured to electrically couple and/or structurally affix the PCB to an external structure; and
at least a portion of the environmental stress indicator is located within a threshold distance from the external connector for detecting and logging mechanical stress applied on the PCB.

6. The electronic device of claim 2, further comprising:
a signal conductor located on between the outer-most layer and the directly-underneath layer or below the directly-underneath layer.

7. The electronic device of claim 1, wherein one or more of the environmental stress indicators are mounted on a surface of the PCB.

8. The electronic device of claim 1, wherein the one or more environmental stresses further comprise temperature stress, mechanical force stress, or a combination thereof.

9. The electronic device of claim 1, wherein the environmental stress indicator is configured to detect and log the one or more environmental stresses occurring post-production.

10. The electronic device of claim 1, further comprising:
a signal path coupled to the environmental stress indicator; and
a measurement circuit coupled to the signal path and configured to detect the change the continuity state.

11. An electronic device, comprising:
a printed circuit board (PCB) core;
an outer-most layer over the PCB core;
a signal trace disposed between the core and the outer-most layer; and
an environmental stress indicator disposed between the outer-most layer and the PCB core, the environmental stress indicator configured to change a continuity state in response to one or more environmental stresses for permanently logging an occurrence of the one or more environmental stresses.

12. The electronic device of claim 11, wherein the environmental stress indicator is configured break and change from a continuous state to a disconnected state in response to mechanical stress applied to the PCB.

13. The electronic device of claim 11, wherein:
the signal trace comprises an outer-most signaling layer; and
the environmental stress indicator is above the outer-most signaling layer.

14. The electronic device of claim 11, wherein:
the signal trace (1) includes a conductive metallic material and (2) corresponds to a minimum width, a minimum thickness, or both; and
the environmental stress (1) includes the same conductive metallic material and (2) has a width less than the minimum width, a thickness less than the minimum thickness, or both.

15. The electronic device of claim 11, wherein:
the signal trace and the environmental stress indicator are connected to form a continuous signal path for providing the continuity state to a measuring circuit that periodically checks for the change in continuity state post-production.

16. An electronic device, comprising:
a printed circuit board (PCB); and
an environmental stress indicator surface mounted to the PCB and configured to change a continuity state in response to one or more environmental stresses for permanently logging an occurrence of the one or more environmental stresses.

17. The electronic device of claim 16, wherein the environmental stress indicator is configured to change from a conductive state to a disconnected state in response to an occurrence of the one or more environmental stresses.

18. The electronic device of claim 16, wherein the environmental stress indicator is configured to change from a disconnected state to a conductive state in response to an occurrence of the one or more environmental stresses.

19. The electronic device of claim 16, wherein the environmental stress indicator is configured to change the continuity state when a mechanical force applied on the PCB post-production exceeds a predetermined force threshold, when a post-production ambient temperature exceed a predetermined temperature threshold, or a combination thereof.

20. The electronic device of claim 16, further comprising:
a measurement circuit mounted on the PCB and electrically coupled to the environmental stress indicator, the measurement circuit configured to periodically check for the change in continuity state.
